(19) United States
(12) Patent Application Publication
(10) Pub. No.: US 2017/0094773 A1
(43) Pub. Date: Mar. 30, 2017

(54) PRINTED CIRCUIT BOARD AND METHOD FOR MANUFACTURING THE SAME

(71) Applicant: Samsung Electro-Mechanics Co., Ltd., Suwon-Si (KR)

(72) Inventors: Il-Jong SEO, Cheongju-si (KR); Ogura ICHIRO, Suwon-Si (KR); Myung-Sam KANG, Hwaseong-si (KR); Tae-Hong MIN, Hwaseong-si (KR)

(73) Assignee: Samsung Electro-Mechanics Co., Ltd., Suwon-Si (KR)

(21) Appl. No.: 15/215,849

(22) Filed: Jul. 21, 2016

(30) Foreign Application Priority Data
Sep. 25, 2015 (KR) 10-2015-0136825

(51) Int. Cl. H05K 1/02; H05K 1/11; H05K 3/40; H05K 3/46

(52) U.S. Cl. CPC H05K 1/0206; H05K 3/4644; H05K 1/115; H05K 3/4038; H05K 2201/06; H05K 2201/09645

(57) ABSTRACT

A printed circuit board and a method of manufacturing the same are provided. The printed circuit board may include a core layer, a metal layer disposed on the core layer, and a heat dissipation unit disposed to pass through the core layer in across a thickness of the core layer.

### CROSS REFERENCE TO RELATED APPLICATION(S)

This application claims the benefit under 35 USC §119(a) of Korean Patent Application No. 10-2015-0136825 filed on Sep. 25, 2015 in the Korean Intellectual Property Office, the entire disclosure of which is incorporated herein by reference for all purposes.

### BACKGROUND

1. Field

The following description relates to a printed circuit board and a method for manufacturing the same.

2. Description of Related Art

In accordance with development of electronic devices with lighter weights and smaller sizes, the number of electronic components to be mounted on a fixed printed circuit board area has been increased and width of and distance between wiring patterns has been also reduced.

High thermal dissipation is needed for circuit boards for electro component package applications to effectively release heat generated from electro components.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In an aspect a printed circuit board is provided. The printed circuit board may include a core layer, a metal layer disposed on the core layer, and a heat dissipation unit disposed to pass through the core layer in across a thickness of the core layer.

In an embodiment, the core layer includes a resin.

In an embodiment, the printed circuit board further includes a through via disposed to pass through the core layer and the metal layer in across a thickness of the core layer. In an embodiment, the insulator is disposed between the through via and the metal layer.

In an embodiment, the printed circuit board further includes an insulator disposed on the metal layer. The printed circuit board may further include a build-up layer disposed on the insulator.

In an embodiment, the heat dissipation unit comprises a metallic material. In an embodiment, the heat dissipation unit comprises one of alumina and carbon. In an embodiment, the heat dissipation unit is in contact with the metal layer.

In an embodiment, the printed circuit board further includes a circuit disposed on the metal layer. In an embodiment, the printed circuit board further includes an adhesion layer formed between the core layer and the metal layer.

In another general aspect, a method for manufacturing a printed circuit board is described. The method may include forming an aperture to pass through a core layer across a thickness of the core layer, disposing a heat dissipation unit in the aperture, and disposing a metal layer on the core layer.

In an embodiment, the forming an aperture includes disposing a first adhesion layer on a first surface of the core layer, and forming a pattern for the aperture on the first adhesion layer.

In an embodiment, the disposing the heat dissipation unit comprises inserting or filling a heat conductive material in the aperture.

In an embodiment, the method further includes disposing a second adhesion layer on a second surface of the core layer following disposing the heat dissipation unit.

In an embodiment, the method further includes providing a through via to pass through the core layer and the metal layer following disposing the metal layer. In an embodiment, the providing a through via includes forming a through hole, disposing an insulator on an inner wall of the through hole, and filling the through hole.

In an embodiment, the method further includes disposing an insulator on the metal layer. In an embodiment, filling the through hole includes filling the through hole with an electrically conductive material.

In an embodiment, the method further includes providing a circuit on the metal layer.

Other features and aspects will be apparent from the following detailed description, the drawings, and the claims.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a schematic diagram illustrating an example of a printed circuit board.

FIG. 2 is a schematic diagram illustrating heat flow of an example of a printed circuit board.

FIG. 3 is a schematic diagram illustrating a cross section of the core layer of a printed circuit board during an example of a method of manufacturing a printed circuit board.

FIGS. 4A-B is a schematic diagram illustrating a cross section of the core layer during formation of an aperture during an example of a method of manufacturing a printed circuit board.

FIG. 5 is a schematic diagram illustrating a cross section of the core layer with heat dissipation unit during an example of a method of manufacturing a printed circuit board.

FIG. 6 is a schematic diagram illustrating a cross section of a core layer having a dissipation unit, and a second adhesion layer disposed thereon during an example of a method of manufacturing a printed circuit board.

FIG. 7 is a schematic diagram illustrating a cross section a core layer having a dissipation unit, and a second adhesion layer and a metal layer disposed thereon during an example of a method of manufacturing a printed circuit board.

FIG. 8 is a schematic diagram illustrating a cross section showing a via hole across the printed circuit board during an example of a method of manufacturing a printed circuit board.

FIG. 9 is a schematic diagram illustrating a cross section showing a via hole across the printed circuit board during an example of a method of manufacturing a printed circuit board.

FIG. 10 is a schematic diagram illustrating a cross section showing a circuit formed on a printed circuit board during an example of a method of manufacturing a printed circuit board.

FIG. 11 is a schematic diagram illustrating a cross section during showing a circuit formed on a printed circuit board an example of a method of manufacturing a printed circuit board.

FIG. 12 is a schematic diagram illustrating a cross section during an example of a method of manufacturing a printed circuit board.

FIG. 13 is a schematic diagram illustrating a cross section during an example of a method of manufacturing a printed circuit board.

FIG. 14 is a flow chart illustrating various operations in an example of a method of manufacturing a printed circuit board.

Throughout the drawings and the detailed description, unless otherwise described or provided, the same drawing reference numerals refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure is thorough, complete, and conveys the full scope of the disclosure to one of ordinary skill in the art.

It will be understood that, although the terms “first,” “second,” “third,” “fourth” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. Similarly, when it is described that a method includes series of steps, a sequence of the steps is not a sequence in which the steps should be performed in the sequence, an arbitrary technical step may be omitted and/or another arbitrary step, which is not disclosed herein, may be added to the method.

The terms used herein may be exchangeable to be operated in different directions than shown and described herein under an appropriate environment. It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Unless indicated otherwise, a statement that a first layer is “on” a second layer or a substrate is to be interpreted as covering both a case where the first layer directly contacts the second layer or the substrate, and a case where one or more other layers are disposed between the first layer and the second layer or the substrate.

The terminology used herein is for the purpose of describing particular examples only, and is not intended to limit the scope of the disclosure in any way. As used herein, the singular forms “a,” “an,” and “the” are intended to include the plural forms as well, unless the context clearly indicates otherwise. It will be further understood that the terms “include” and/or “have,” when used in this specification, specify the presence of stated features, numbers, operations, elements, components, or combinations thereof, but do not preclude the presence or addition of one or more other features, numbers, operations, elements, components or combinations thereof.

Unless otherwise defined, all terms, including technical and scientific terms, used herein have the same meaning as commonly understood by one of ordinary skill in the art to which this description pertains. It will be further understood that terms, such as those defined in commonly used dictionaries, should be interpreted as having a meaning that is consistent with their meaning in the context of the relevant art and are not to be interpreted in an idealized or overly formal sense unless expressly so defined herein.

Words describing relative spatial relationships, such as “below”, “beneath”, “under”, “lower”, “bottom”, “above”, “over”, “upper”, “top”, “left”, and “right”, may be used to conveniently describe spatial relationships of one device or elements with other devices or elements. Such words are to be interpreted as encompassing a device oriented as illustrated in the drawings, and in other orientations in use or operation. For example, an example in which a device includes a second layer disposed above a first layer based on the orientation of the device illustrated in the drawings also encompasses the device when the device is flipped upside down in use or operation.

As used herein, the term “about” means plus or minus 10% of the numerical value of the number with which it is being used. Therefore, about 50% means in the range of 45%-55%.

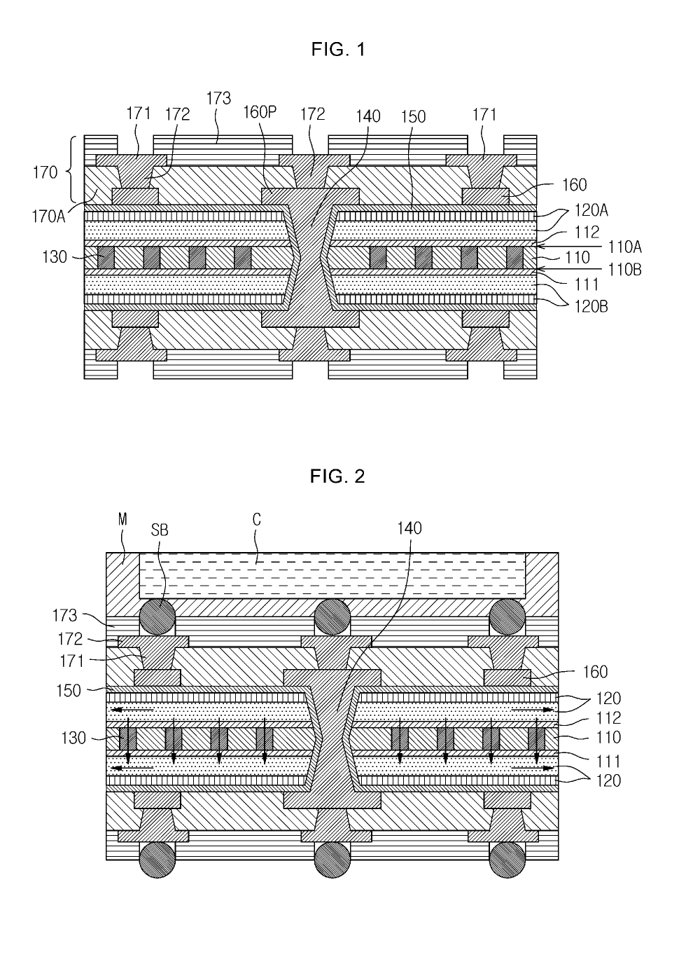

FIG. 1 is a diagram illustrating an example of a printed circuit board and FIG. 2 is a diagram illustrating heat flow for an example of a printed circuit board.

Referring to FIGS. 1 and 2, a printed circuit board according to an example may include a core layer 110, a metal layer 120, and a heat dissipation unit 130, wherein the metal layer 120 is disposed on the core layer 110 and the heat dissipation unit 130 is disposed to pass through the core layer 110 in across a thickness of the core layer 110.

The core layer 110 may be a resin. The core layer 110 may include a thermosetting resin such as an epoxy resin and/or a thermoplastic resin such as, for example, polyimide. Polyimide is a high ductile material that allows easy handling and lowers the probability of cracking the core layer 110 when the core layer 110 is sawed or diced into unit boards.

The core layer 110 may further include a reinforcing material such as, for example, a fabric reinforcing material, or an inorganic filler. In an embodiment, the fabric reinforcing material is disposed in a prepreg in which a glass cloth is impregnated into a resin.

The metal layer 120 may be laminated on the core layer 110 to improve heat dissipation property and increase strength. Examples of the metal layer 120 include, without limitation, Cu, Al, Mg, Ti, Hf, Zn, W, and Mo. In some embodiments, the metal layer 120 is a heat-conducting alloy such as, for example, invar and kovar.

In an embodiment, the metal layer 120 is laminated on both upper surface and lower surface of the core layer 110. In an embodiment, the metal layer 120 is disposed as a sheet that can be laminated on the core layer 110.

The metal layer 120 may include two or more layers. In an embodiment, the metal layer 120 may include a copper layer and an invar layer. In such an embodiment, the invar layer may be disposed on the core layer 110 with the copper layer being disposed on the invar layer. The copper layer, in such an embodiment, improves the heat dissipation, and the invar layer improves the strength and prevents warpage issues.

Because changes of physical properties of invar are marginal at temperatures lower than 200° C., invar may be advantageous for reducing warpage issues in a printed circuit board used in circuits operating at high temperatures.

The thickness of metal layer 120 may be optimized to provide desired heat dissipation while keeping the warpage reduction effects minimal. For example, metal layer 120 may have a thickness of about 20 μm to about 100 μm.

Some embodiments may include adhesion layers 111, 112 disposed between the core layer 110 and the metal layer 120.

The adhesion layers 111, 112 may include, without limitation, a double-sided tape, or an adhesive coating. In some embodiments, the adhesion layers 111, 112 include, without limitation, a bismaleimide-triazine (BT) resin composition or an epoxy resin composition. The BT resin composition may include BT, bismaleimide (BMI) epoxy, a core shell rubber (CSR), an amino group-containing epoxy and an epoxy. The epoxy resin composition may include an amino group-containing epoxy, a carboxyl group-containing epoxy, a CSR and an epoxy.

In some embodiments, the adhesion layers 111, 112 are formed of the same material as the core layer 110 to increase the adhesion because, in such embodiments, the interface 110A between the core layer 110 and the adhesion layer 111, and the interface 110B between the core layer 110 and the adhesion layer 112 is eliminated.

In some embodiments, the adhesion layers 111, 112 have a thickness of about 2 μm to about 20 μm for enable optimization of adhesion reliability.

The heat dissipation unit 130 may be inserted into the core layer 110 to increase the heat dissipation across a thickness of the printed circuit board. In an embodiment, the heat dissipation unit 130 may pass through from a first surface of the core layer 110 to a second surface of the core layer 110. In such an embodiment, the ends of the heat dissipation unit 130 are in contact with the metal layer 120 enabling heat transmission from the metal layer 120A on the first surface of the core layer 110 to the metal layer 120B on the second surface of the core layer 110 through the heat dissipation unit 130.

In some embodiments, more than one heat dissipation unit 130 are disposed spaced apart from each other across the thickness of the core layer 110. In such embodiments, the heat dissipation unit 130 may form columns across the thickness of the core layer 110, and may have any suitable cross-sectional shape such as, for example, a square, a rectangle, a circle, or any regular or irregular convex polygon.

The heat dissipation unit 130 may be a metal or a non-metal having high heat conductivity. Examples of non-metallic heat dissipation units include, without limitation, alumina and carbon.

Referring to FIG. 2, an electronic component C may be mounted on a first surface of the printed circuit board using a solder ball SB and then molded with a molding material M. The heat dissipation unit 130 may transfer heat from the electronic component C mounted on the first surface of the printed circuit board to a second surface of the printed circuit board. The heat dissipation unit 130 may transfer heat perpendicularly across a thickness of the printed circuit board, while the metal layer 120 may transfer heat horizontally along the surface of the printed circuit board.

When there is no heat dissipation unit 130, heat may not be transferred by the core layer 110, resulting in poor heat dissipation, and increasing the temperature of the printed circuit board and components in contact therewith. However, when the heat dissipation unit 130 is disposed in the core layer 110, heat transfer from one surface of the core layer 110 to the other surface may be possible, resulting in improved heat dissipation.

In an embodiment, the printed circuit board further includes a through via 140.

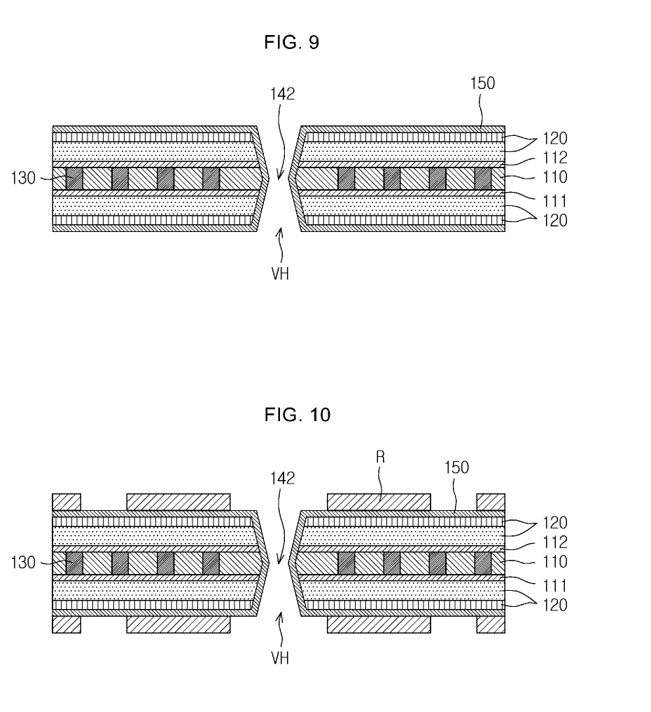

The through via 140 may pass through across a thickness of the core layer 110 and the metal layer 120 of the printed circuit board. The through via 140 is formed by forming a via hole VH (see FIGS. 9, 10) through the core layer 110 and the metal layer 120 and filling the via hole VH with a conducting material.

The via hole VH may include a first hole 141 and a second hole 142 (see FIGS. 8-10). In an embodiment, the via hole VH is formed by forming the first hole 141 in the metal layer 120 and then forming the second hole 142 in the core layer 110 to be corresponded to the first hole 141.

In an embodiment, the first hole 141 is formed through a process such as, for example, etching of the metal layer 120 and the second hole 142 is formed using a process such as, for example, laser drilling of the core layer 110. The etching process for forming the first hole 141 may include iron chloride solution as an etchant.

In an embodiment, the through via 140 electrically connects circuits disposed on different layers of the printed circuit board and transmits signals between the electronic component C and a main board.

In some embodiments, because the through via 140 is conductive, it is insulated from the metal layer 120. In such embodiments, an insulator 150 is disposed between the through via 140 and the metal layer 120. In some embodiments, the insulator 150 is additionally disposed on the metal layer 120. The insulator 150 disposed on the metal layer 120 may insulate the metal layer 120 from a circuit 160 disposed thereon.

The insulator 150 may not be disposed between the core layer 110 and the through via 140, but disposed between the through via 140 and the metal layer 120 and on an upper surface of the metal layer 120 away from the core layer 110.

Referring back to FIG. 1, in an embodiment, the insulator 150 is disposed on a portion of the core layer 110. In such an embodiment, the insulator 150 is, additionally, disposed on the entire inner wall of the via hole VH. In other words, the insulator 150 is integrally formed on the metal layer 120 and the inner wall of the via hole VH.

The insulator 150 may include a thermosetting resin such as, for example, an epoxy resin and a thermoplastic resin such as, for example, a polyimide. In various embodiments, a thickness of the insulator 150 is less than that of the core layer 110.

A pad 160P may be disposed on the through via 140 and a circuit 160 may be disposed on the metal layer 120. In an embodiment, the circuit 160 and the pad 160P are electrically connected. In an embodiment, the insulator 150 is disposed between the metal layer 120 and the circuit 160.

The printed circuit board, in some embodiments, further includes a build-up layer 170 disposed on the metal layer 120. The build-up layer 170 includes an insulating layer 170A, and a circuit pattern including a circuit 171 disposed on the insulating layer 170A, and a via 172 electrically connecting the circuit 160 with the circuit 171. The insulating layer 170A may be laminated on the metal layer 120 to cover, and electrically separate the circuit 160 disposed on the metal layer 120 from the circuit 171 disposed on insulating layer 170A.

In an embodiment, a heat dissipation via may be disposed in the build-up layer 170. The heat dissipation via may be directly in contact with the metal layer 120. That is, the heat dissipation via passes through the insulating layer 150 to be in contact with the metal layer 120. In an embodiment, the heat dissipation via is electrically connected with the circuit 171 and transfers the heat from the electronic component C to the metal layer 120 (see FIG. 2).

The insulating layer disposed at the topmost part of the build-up layer 170 may be a solder resist 173. The solder resist 173 may be disposed to protect the circuit 171 and expose a part of the circuit 171 for an external device such as an electronic component to be connected.

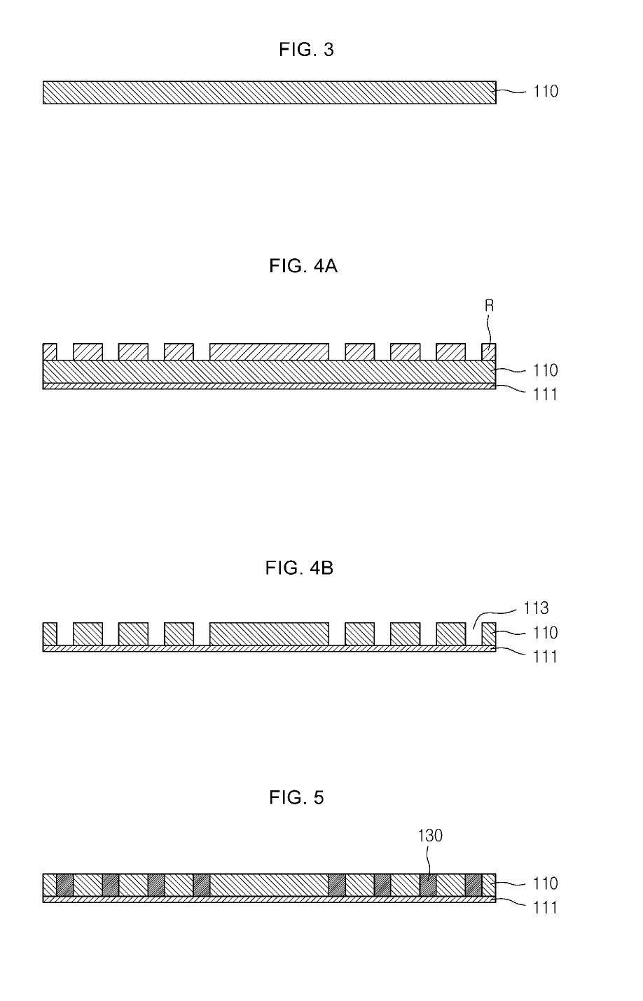

FIG. 3 to FIG. 13 are schematic diagrams illustrating cross sections of various stages of a printed circuit board manufactured using an example of a method for manufacturing a printed circuit board.

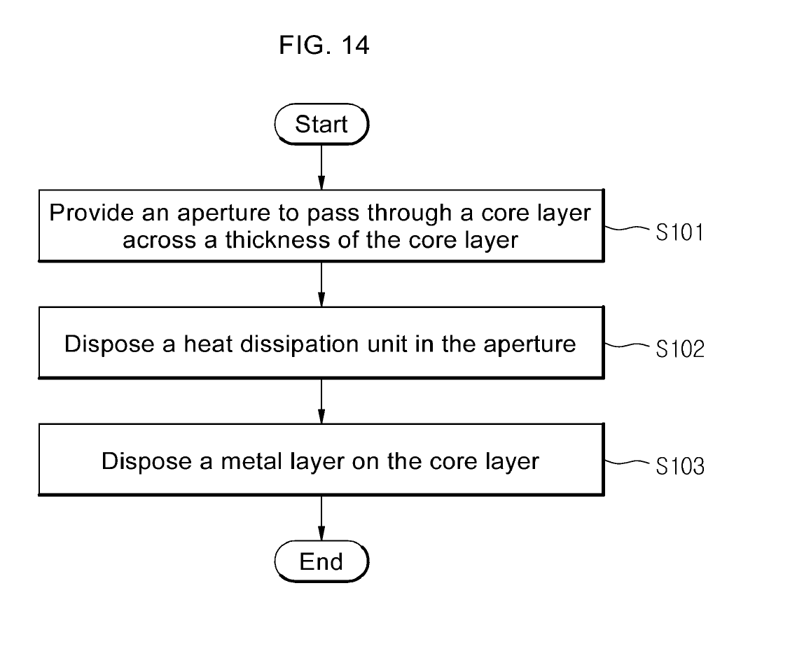

FIG. 14 is a flow chart illustrating various operations in an example of a method of manufacturing a printed circuit board. The method of manufacturing includes at S101 providing an aperture to pass through a core layer across a thickness of the core layer, at S102 disposing a heat dissipation unit in the aperture and at S103 disposing a metal layer on the core layer.

The aperture 113 may be provided to pass through from a first surface to a second surface of the core layer 110. More than one apertures 113 may be provided to be spaced apart to each other along the cross section of the core layer 110.

A method for providing the aperture 113 may include disposing a first adhesion layer 111 on the first surface of the core layer 110 and patterning the aperture 113 on the core layer 110.

The first adhesion layer 111 may be disposed by the same method to form the adhesion layer described above. The first adhesion layer 111 may support the core layer 110. When the aperture 113 passes through from the first surface to the second surface of the core layer 110, the heat dissipation unit 130 may be disposed on the first adhesion layer 111.

Referring to FIGS. 4A and 4B, the operation for patterning an aperture 113 may include disposing a photo resist R on the core layer 110, patterning the photo resist R and forming the aperture 113 corresponding to the patterned photo resist R. The photo resist R may be patterned using a photolithography process. In an embodiment, forming the aperture 113 includes etching the core layer 110 using a suitable etching method such as, for example, a wet etching method or a dry etching method. In an embodiment, forming the aperture 113 includes ion milling the core layer 110 corresponding to the photo resist.

After forming the aperture 113, the photo resist R may be eliminated (see FIG. 4B). In some embodiments, the core layer 110 is formed of a photosensitive insulating material (PID). In such embodiments, the aperture 113 may be provided directly using a photolithography process without the photo resist R.

Referring to FIG. 5, the operation of providing a heat dissipation unit 130 may include inserting or filling the heat dissipation unit 130 inside the aperture 113 of the core layer 110. When the heat dissipation unit 130 is solid, the heat dissipation unit 130 may be inserted inside the aperture 113, while when it is fluid, it may be filled into the aperture 113.

For example, when the heat dissipation unit 130 is a solid metal, it may be inserted inside the aperture 113 after it is molded according to the size of the aperture 113. When the heat dissipation unit 130 is a conductive paste, it may be filled into the aperture 113 using a suitable method such as, for example, screen printing. That is, the heat dissipation unit 130 may be selectively filled inside the aperture 113 by using a mask having holes corresponding to the aperture 113.

In some embodiments, the heat dissipation unit 130 is filled into the aperture 113 at a depth greater than the depth of the aperture 113 and then a part of the upper part of the heat dissipation unit 130 is removed to be equal to the depth of the aperture 113.

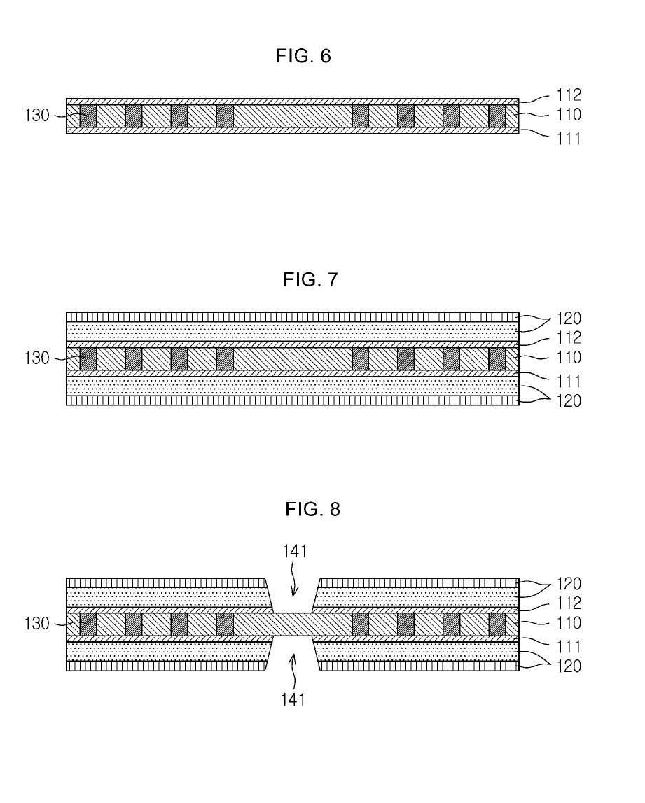

Referring to FIG. 6, in an embodiment, a second adhesion layer 112 is disposed on the second surface of the core layer 110 after providing the heat dissipation unit 130 inside the aperture 113. The heat dissipation unit 130 is stabilized inside the aperture 113 by the first adhesion layer 111 and the second adhesion layer 112.

Referring to FIG. 7, in an embodiment, a metal layer 120 is disposed on the core layer 110. In some embodiments, the metal layer 120 is formed in two layers as has been described elsewhere herein.

Referring to FIGS. 8 and 9, a via hole VH is then provided to pass through both the metal layer 120 and the core layer 110. As shown in FIG. 8, a first hole 141 may be formed by removing a portion of the metal layer 120. As shown in FIG. 9, a second hole 142 may be formed by removing a portion of the core layer 110. The first hole 141 and the second hole 142 are aligned with each other to form the via hole VH. In an embodiment, the first hole 141 is formed by etching the metal layer 120 using a suitable etchant such as, for example, an iron chloride etchant. The second hole 142 is formed by drilling through the core layer 110 using, for example, a laser drill.

In an embodiment, the metal layer on the boundary between unit boards may be removed at the same time as the formation of the via hole VH. When the core layer on the boundary between unit boards is removed, the metal layer on the boundary between unit boards may be removed in advance to facilitate separation of the unit boards.

An insulator 150 may be disposed between the via hole VH and the metal layer 120 and further disposed on the metal layer 120.

In some embodiments, the insulator 150 is disposed after providing first hole 141, but before providing the second hole 142. In such embodiments, after the first hole 141 is formed as shown in FIG. 8, the insulator 150 is disposed before forming the second hole 142 shown in FIG. 9. The insulator 150 is also disposed on an inside wall the first hole 141 and on the metal layer 120.

Because the second hole 142 is formed after the insulator 150 is disposed, the insulator 150 is not present on a side surface of the core layer 110 in a final product.

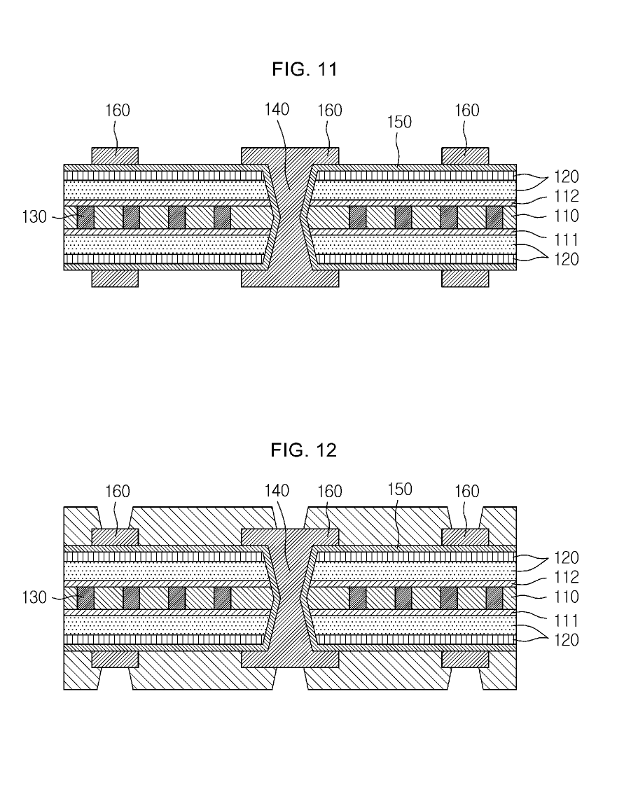

As shown in FIG. 10 and FIG. 11, in an embodiment, a circuit 160 is disposed on the metal layer 120. The circuit 160 and the through via 140 may be provided in a same operation.

The circuit 160 may be formed by an additive process, a subtractive process, or a semi-additive process. However, the method for forming the circuit 160 may not be limited thereto. The circuit 160 may be formed of a metal such as, for example, Cu.

When the circuit 160 is coated, the via hole VH may be filled to form the through via 140.

Referring to FIG. 12, a build-up layer 170 may be formed on the metal layer 120 and the insulator 150 may be formed between the metal layer 120 and the build-up layer 170.

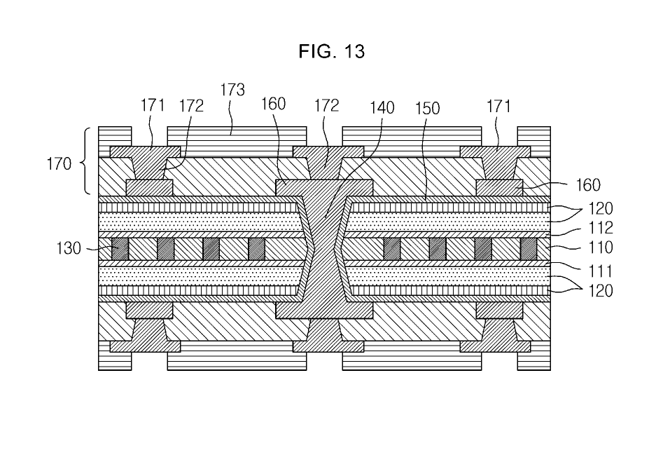

Referring to FIG. 13, the topmost layer of the build-up layer 170 may be a solder resist 173 to protect a circuit 171 but expose a part of the circuit 171.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board comprising:
a core layer;
a metal layer disposed on the core layer; and
a heat dissipation unit disposed to pass through the core layer in across a thickness of the core layer.

2. The printed circuit board of claim 1, wherein the core layer comprises a resin.

3. The printed circuit board of claim 1, further comprising a through via disposed to pass through the core layer and the metal layer in across a thickness of the core layer.

4. The printed circuit board of claim 3, wherein an insulator is disposed between the through via and the metal layer.

5. The printed circuit board of claim 1, further comprising an insulator disposed on the metal layer.

6. The printed circuit board of claim 5, further comprising a build-up layer disposed on the insulator.

7. The printed circuit board of claim 1, wherein the heat dissipation unit comprises a metallic material.

8. The printed circuit board of claim 1, wherein the heat dissipation unit comprises one of alumina and carbon.

9. The printed circuit board of claim 1, wherein the heat dissipation unit is in contact with the metal layer.

10. The printed circuit board of claim 1, further comprising a circuit disposed on the metal layer.

11. The printed circuit board of claim 1, further comprising an adhesion layer formed between the core layer and the metal layer.

12. A method for manufacturing a printed circuit board comprising:
providing an aperture to pass through a core layer across a thickness of the core layer;
disposing a heat dissipation unit in the aperture; and
disposing a metal layer on the core layer.

13. The method of claim 12, wherein the providing an aperture comprises:
disposing a first adhesion layer on a first surface of the core layer; and
forming a pattern for the aperture on the first adhesion layer.

14. The method of claim 12, wherein the disposing the heat dissipation unit comprises inserting or filling a heat conductive material in the aperture.

15. The method of claim 12, further comprising disposing a second adhesion layer on a second surface of the core layer following disposing the heat dissipation unit.

16. The method of claim 12, further comprising providing a through via to pass through the core layer and the metal layer following disposing the metal layer.

17. The method of claim 16, wherein the providing a through via comprises:
providing a through hole;
disposing an insulator on an inner wall of the through hole; and
filling the through hole.

18. The method of claim 12, further comprising disposing an insulator on the metal layer.

19. The method of claim 12, wherein filling the through hole comprises filling the through hole with an electrically conductive material.

20. The method of claim 12, further comprising providing a circuit on the metal layer.
